(19) United States
(12) Patent Application Publication
(10) Pub. No.: US 2022/0277935 A1
(43) Pub. Date: Sep. 1, 2022

(54) MICROWAVE PLASMA PROCESSING APPARATUS

(71) Applicant: Tokyo Electron Limited, Tokyo (JP)

(72) Inventors: Taro IKEDA, Yamanashi (JP); Tomohito KOMATSU, Yamanashi (JP); Eiki KAMATA, Yamanashi (JP); Mikio SATO, Yamanashi (JP)

(21) Appl. No.: 17/663,907

(22) Filed: May 18, 2022

Related U.S. Application Data
(62) Division of application No. 16/214,613, filed on Dec. 10, 2018.

(30) Foreign Application Priority Data
Dec. 14, 2017 (JP) 2017-239892
Oct. 22, 2018 (JP) 2018-198732

(51) Int. Cl. H01J 37/32; B01J 19/08; H05H 1/46; C23C 16/511

(52) U.S. Cl. CPC H01J 37/32192; B01J 19/08; H05H 1/46; C23C 16/511

(57) ABSTRACT

A microwave plasma processing apparatus includes a microwave supply part configured to supply a microwave; a microwave emission member provided on a ceiling of a process chamber and configured to emit the microwave supplied from the microwave supply part; and a microwave transmission member configured to close an opening provided in the ceiling and made of a dielectric substance that transmits the microwave transmitted to a slot antenna. The ceiling has at least two recesses provided on an outer side of the opening, each of the at least two recesses having a depth different from each other.

### CROSS-REFERENCE TO RELATED APPLICATIONS

The present application is a divisional application of U.S. patent application Ser. No. 16/214,613 filed on Dec. 10, 2018, which is based on and claims priority to Japanese Patent Application No. 2017-239892, filed on Dec. 14, 2017, and Japanese Patent Application No. 2018-198732, filed on Oct. 22, 2018 in the Japan Patent Office, the disclosures of which are incorporated by reference herein in their entirety.

### BACKGROUND OF THE INVENTION

### 1. Field of the Invention

The disclosure relates to a microwave plasma processing apparatus.

### 2. Description of the Related Art

A plasma processing apparatus is known that introduces a microwave into a vacuum chamber from a microwave introducing part through a transmission window provided at an opening of a ceiling thereof and performs a plasma process on a substrate by action of plasma generated from a gas by power of the microwave (see, Patent Document 1). The plasma processing apparatus has a choke groove that decreases propagation of the microwave around the opening. The choke groove has a length of propagation path of an approximately λ/4 relative to a free-space wavelength λ of plasma, and reduces the propagation of microwave.

However, in Patent Document 1, a position of the groove is designed corresponding to the length of propagation path of the microwave introduced into the vacuum chamber, and an increase in plasma density by optimizing a shape of the groove is not considered.

One of the methods for increasing the plasma density includes an increase in input power, but in this case, a plasma source having great maximum output power has to be prepared. Moreover, a production cost increases due to greater consumption of power during the plasma process. Hence, a structure of plasma processing apparatus to increase the plasma density without increasing the input power is desired.

### RELATED-ART DOCUMENTS

### Patent Document

[Patent Document 1] Japanese Patent Application Publication No. 2003-45848
[Patent Document 2] Japanese Patent Application Publication No. 2004-319870
[Patent Document 3] Japanese Patent Application Publication No. 2005-32805
[Patent Document 4] Japanese Patent Application Publication No. 2009-99807
[Patent Document 5] Japanese Patent Application Publication No. 2010-232493
[Patent Document 6] Japanese Patent Application Publication No. 2016-225047

### SUMMARY OF THE INVENTION

In response to the above discussed problems, embodiments of the present disclosure aim at providing a plasma processing apparatus having a structure that can increase plasma density.

According to one embodiment of the present disclosure, there is provided a microwave plasma processing apparatus that includes a microwave supply part configured to supply a microwave, and a microwave emission member provided on a ceiling of a process chamber and configured to emit the microwave supplied from the microwave supply part. A microwave transmission member is provided to close an opening provided in the ceiling and made of a dielectric substance that transmits the microwave transmitted to a slot antenna via the microwave emission member. The ceiling has at least one recess having a depth in a range of λₛₚ/4±λₛₚ/8 on an outer side of the opening when a wavelength of a surface wave of the microwave traveling through the microwave transmission member and propagating along a surface of the ceiling from the opening is taken as λₛₚ.

Additional objects and advantages of the embodiments are set forth in part in the description which follows, and in part will become obvious from the description, or may be learned by practice of the invention. The objects and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a cross-sectional view illustrating an example of a microwave plasma processing apparatus according to an embodiment;

FIG. 2 is a diagram illustrating an example of a ceiling of a microwave plasma processing apparatus according to an embodiment (an A-A cross section in FIG. 1);

FIGS. 3A through 3D are diagrams illustrating examples of a recess of a microwave plasma processing apparatus according to an embodiment;

FIG. 4 is a diagram illustrating an example of electric field interception efficiency of recesses of microwave plasma processing apparatuses according to an embodiment and a comparative example;

FIG. 5 is a diagram for explaining electric field interception efficiency of recesses of microwave plasma processing apparatuses according to an embodiment and a comparative example;

FIG. 6 is a diagram showing an example of an evaluation result of electric field interception efficiency of recesses of microwave plasma processing apparatuses according to an embodiment and a comparative example;

FIG. 7 is a diagram showing an example of an evaluation result of electric field interception efficiency of recesses of microwave plasma processing apparatuses according to an embodiment and a comparative example;

FIG. 8 is a diagram illustrating an example of a ceiling of a first variation of a microwave plasma processing apparatus according to an embodiment (the A-A cross section in FIG. 1);

FIG. 9 is a diagram illustrating an example of a ceiling of a second variation of a microwave plasma processing apparatus according to an embodiment (the A-A cross section in FIG. 1);

FIGS. 10A and 10B are diagrams illustrating an example of a ceiling of a third variation of a microwave plasma processing apparatus according to an embodiment;

FIGS. 11A and 11B are diagrams illustrating an example of a ceiling of a fourth variation of a microwave plasma processing apparatus according to an embodiment;

FIG. 12 is a diagram showing an example of a relationship between a wavelength λₛₚ of a surface wave of a microwave and electron density of plasma of the ceiling of the fourth variation of the microwave plasma processing apparatus according to an embodiment; and

FIG. 13 is a diagram illustrating a system using calculations for introducing a relationship between a wavelength λₛₚ of a surface wave of a microwave and electron density of plasma.

### DETAILED DESCRIPTION OF THE PREFERRED EMBODIMENTS

Embodiments of the present disclosure are described below, with reference to the accompanying drawings. Note that elements having substantially the same configuration may be given the same reference numerals and overlapping descriptions thereof may be omitted.

[Microwave Plasma Processing Apparatus]

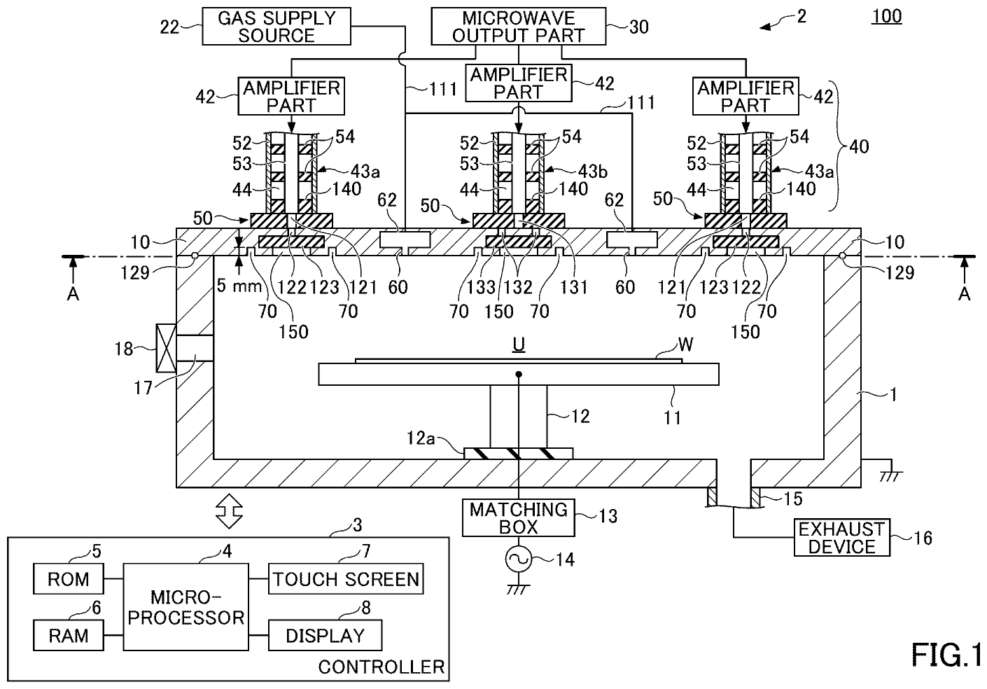

To begin with, a microwave plasma processing apparatus 100 according to an embodiment of the present disclosure is described below with reference to FIG. 1. FIG. 1 is a cross-sectional view illustrating an example of the microwave plasma processing apparatus 100 according to the embodiment of the present disclosure. The microwave plasma processing apparatus includes a process chamber 1 to accommodate a wafer W therein. An upper portion of the process chamber 1 is opened, and the opening is openable and closable by a lid body 10. Thus, the lid body 10 forms a ceiling of the process chamber 1.

The microwave plasma processing apparatus 100 performs a predetermined plasma process on a semiconductor wafer W (which is hereinafter referred to as a “wafer W”) with surface wave plasma of a microwave that propagates along the surface of the ceiling. The predetermined plasma process includes, for example, an etching process, a film deposition process, an ashing process and the like.

The process chamber 1 is an approximately cylindrical container that is made of a metal material such as aluminum and stainless steel. The process chamber 1 is hermetically formed and grounded to the earth. A support ring 120 is provided in a contact surface between the process chamber 1 and the lid body 10, and thus the inside of the process chamber 1 is hermetically sealed. The lid body 10 is made of a metal such as aluminum.

A microwave plasma source 2 includes a microwave output part 30, a microwave transmittal part 40, and a microwave emission member 50. The microwave output part 30 outputs a microwave by splitting into multiple paths. The microwave output part 30 and the microwave transmittal part 40 are an example of a microwave supply part that supplies a microwave.

The microwave transmittal part 40 transmits the microwave output from the microwave output part 30. A peripheral microwave introducing mechanism 43a and a central microwave introducing mechanism 43b provided in the microwave transmittal part 40 have functions of introducing the microwave output from the amplifier part 42 into microwave emission members 50 and matching the impedance. The microwave emission members 50 are provided on the lid body 10 of the process chamber 10.

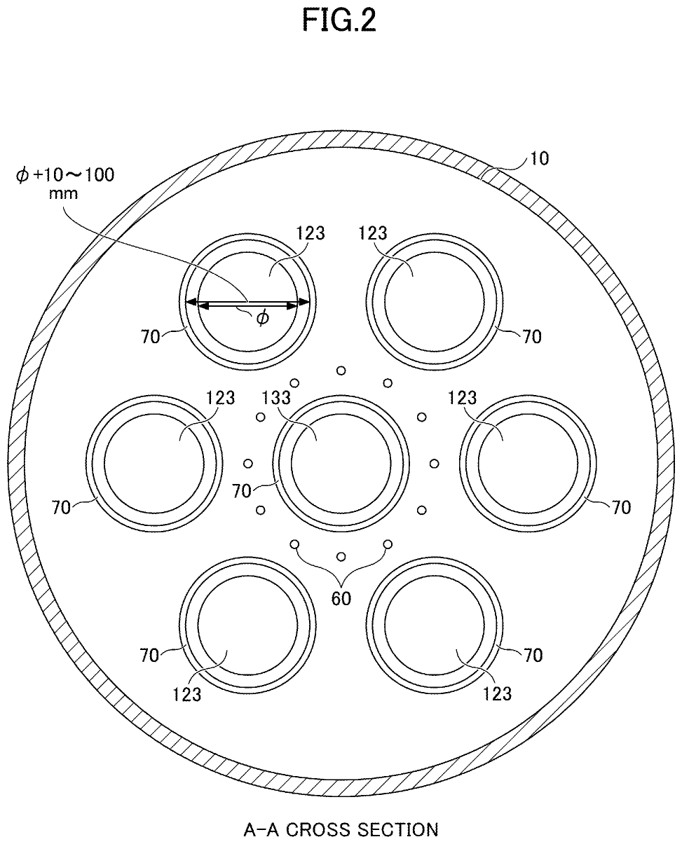

Six microwave transmission members 123 corresponding to the six peripheral microwave introducing mechanism 43a are evenly spaced in a circumferential direction of the lid body 10 under the microwave emission members 50 (see FIG. 2 illustrating an A-A plane in FIG. 1). Moreover, a single microwave transmission member 133 corresponding to the central microwave introducing mechanism 43b is arranged at the center of lid body 10. The microwave transmission members 123 and the microwave transmission member 133 are embedded in the lid body 10, and its circular lower surface is exposed to the inside of the process chamber 1. The lower surfaces of the microwave transmission members 123 and 133 are positioned on a side of slots 122 and 132 on a lower surface of the ceiling.

Cylindrical outer conductors 52 and rod-like inner conductors 53 provided therein are arranged concentrically in the peripheral microwave introducing mechanisms 43a and the central microwave introducing mechanism 43b, and microwave transmission channels 44 are formed between the outer conductors 52 and the inner conductors 53.

The peripheral microwave introducing mechanisms 43a and the central microwave introducing mechanisms 43b include slugs 54 and impedance adjustment members 140 positioned at tips thereof. The slugs 54 are made of a dielectric substance. The slugs 54 have a function of matching the impedance of load (plasma) in the process chamber 1 with characteristic impedance of a microwave power source in the microwave output part 30 by being moved. The impedance adjustment members 140 are made of a dielectric substance, and adjust the impedance of the microwave transmission channels 44 by relative permittivity thereof.

The microwave emission members 50 are formed of disk-shaped members that transmit microwaves. The microwave transmission members 123 and 133 are provided under the microwave emission members 50 via the slots 122 and 132 formed in the lid body 10 so as to close the opening 150 of the lid body 10, respectively. Here, the slots 122 and 132 and portions surrounding the slots 122 and 132 of the lid body 10 constitute slot antennas.

The microwave transmission members 123 and 133 are made of a dielectric substance. The microwave emission members 50 have spaces 121 and 131 at the center, and emit the microwaves to the microwave transmission members 123 and 133 through the slots 122 and 123 connected to the spaces 121 and 131. The microwave transmission members 123 and 133 serve as dielectric windows to uniformly form surface wave plasma of the microwave at the surface of the ceiling.

The microwave transmission members 123 and 133 may be made of, for example, quartz, ceramics such as alumina (Al₂O₃), fluorine-based resin such as polytetrafluoroethylene or polyimide-based resin.

The microwave emission members 50 are made of a dielectric substance having the relative permittivity that is greater than the relative permittivity of a vacuum. Due to this, the microwave emission members 50 allow the wavelength of microwaves transmitting through the microwave emission members 50 to be made shorter than the microwaves transmitting through the vacuum, thereby downsizing antenna shapes including the slots 122 and 132.

Such a configuration enables the microwaves output from the microwave output part 30 to travel into the microwave emission members 50 by way of the microwave transmission channels 44 and to travel into the process chamber 1 from the microwave emission members 50.

Here, numbers of the peripheral microwave introducing mechanisms 43a and the central microwave Introducing mechanism 43b are not limited to numbers illustrated in the present embodiments. For example, providing only a single central microwave introducing mechanism 43b while not providing any peripheral microwave introducing mechanism 43a is possible. In other words, the number of the peripheral microwave introducing mechanisms 43a may be zero, or may be one or more.

The lid body 10 is made of a metal such as aluminum, and includes gas introducing parts 62 having a shower structure therein. A gas supply source 22 is connected to the gas introducing parts 62 via gas supply pipes 111. A gas is supplied from the gas supply source 22, and is supplied into the process chamber 1 from a plurality of gas supply holes 60 of the gas supply parts 62. The gas introducing parts 62 are an example of a gas showerhead that supplies a gas from the plurality of gas supply holes 60 formed in the ceiling of the process chamber 1. An example of the gas includes, for example, Ar gas, or a combination gas of Ar gas and N₂ gas.

A pedestal 11 to receive a wafer W is provided in the process chamber 1. A support member 12 stands on an insulating member 12a and supports the center of the bottom of the pedestal 11. An insulating member (ceramics or the like) having an electrode for radio frequency therein or a metal such as alumited (anodized) aluminum is cited as an example that forms the pedestal 11 and the support member 12. The pedestal 11 may include an electrostatic chuck, a temperature control mechanism, a gas flow passage to supply a heat transfer gas to a back surface of the wafer W and the like.

A radio frequency bias power source 14 is connected to the pedestal 11 through a matching box 13. By supplying radio frequency power to the pedestal 11 from the radio frequency bias power source 14, ions in plasma are attracted to the wafer W side. Here, the radio frequency bias power source 14 does not have to be provided depending on characteristics of the plasma process.

An exhaust pipe 15 is connected to the bottom part of the process chamber 1, and an exhaust device 16 containing a vacuum pump is connected to the exhaust pipe 15. By operating the exhaust device 16, the process chamber 1 is evacuated, thereby decreasing the pressure in the process chamber 1 to a predetermined degree of vacuum at high speed. A side wall of the process chamber 1 includes a transfer port 17 for transferring a wafer W and a gate valve 18 to open and close the transfer port 17.

A controller 3 controls each part of the microwave plasma processing apparatus 100. The controller 3 includes a microprocessor 4, a ROM (Read Only Memory) 5, a RAM (Random Access Memory) 6. The ROM 5 and RAM 6 store a process sequence and a process recipe including a control parameter of the microwave plasma processing apparatus 100. The microprocessor 4 controls each part of the microwave plasma processing apparatus 100 based on the process sequence and the process recipe. Moreover, the controller 3 includes a screen panel 7 and a display 8, which can receive an input when performing predetermined control in accordance with the process sequence and the process recipe and can display the result and the like.

The surface waves of the microwaves emitted through the microwave emission members 50, the slots 122 and 123, and the microwave transmission members 123 and 133 propagate along the surface of the ceiling. Then, an electric field of the surface wave ionizes and dissociates a gas, and generates surface wave plasma of the microwave in the vicinity of the surface of the ceiling. The wafer W is processed with plasma in a process space U between the ceiling of the process chamber 1 and the pedestal 11 using the surface wave plasma.

[Recess]

The surface (back surface) of the ceiling in the lid body 10 of the microwave plasma processing apparatus 100 having such a configuration according to an embodiment is described below with reference to FIG. 2 illustrating an A-A plane of FIG. 1. In the surface of the ceiling, the six microwave transmission members 123 are spaced in the circumferential direction on the peripheral side, and the single microwave transmission member 133 is provided at the center. Each of the microwave transmission members 123 is exposed from the peripheral openings 150 of the ceiling, and the microwave transmission member 133 is exposed from the central opening 150 of the ceiling. The ceiling includes seven recesses (grooves) 70 formed into a ring shape so as to surround each of the openings 150 from which the microwave transmission members 123 and 133 are exposed.

When a wavelength of the surface wave of the microwave that propagates along the surface of the ceiling from the opening 150 of the ceiling after traveling through the microwave transmission members 123 or 133 is taken as λₛₚ, each recess 70 is formed to have a thickness of λₛₚ/4, that is, about 5 mm to about 7 mm. Here, the depth of the recesses 70 is not limited to λₛₚ/4, but may be in a rage of λₛₚ/4±λₛₚ/8.

Furthermore, as illustrated in FIG. 2, the diameter of the inner peripheral side of the recesses 70 is in a range of φ+10 nm to 100 nm relative to the diameter cp of the opening 150 from which the microwave transmission members 123 and 133 are exposed in the ceiling. When the diameter on the inner peripheral side of the recesses 70 is in a range of φ+10 nm to 100 nm, a plurality of ring-shaped recesses 70 may be formed concentrically.

[Evaluation of Recesses]

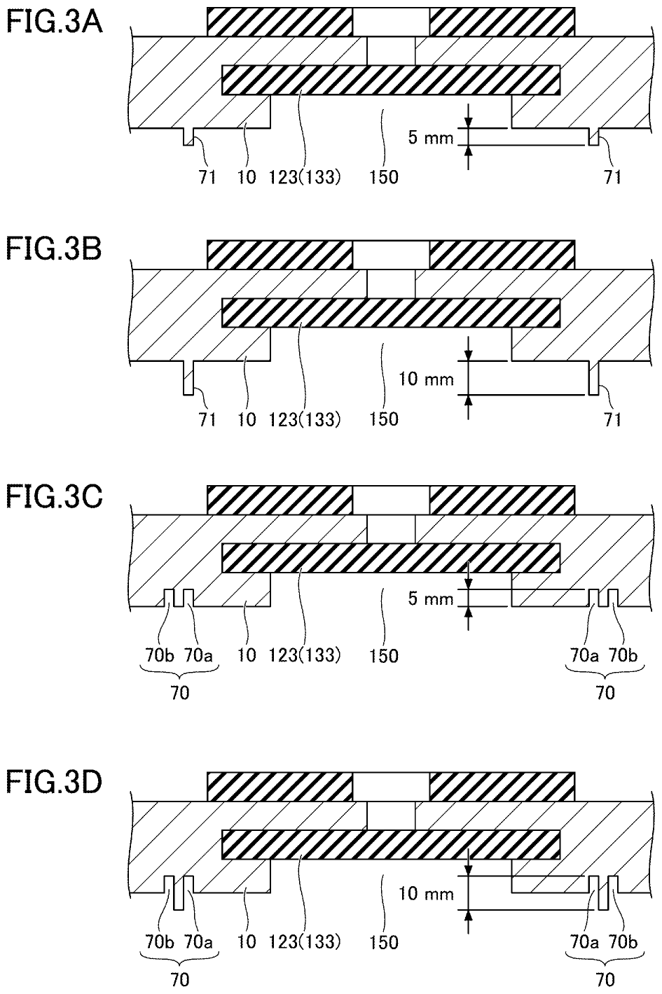

Next, an example of an evaluation result of the recesses is described below with reference to FIGS. 3A through 3D. FIG. 3A and FIG. 3B are comparative examples, and a protrusion 71 is formed into a ring shape in the ceiling so as to surround each of the openings 150 from which the microwave transmission members 123 and 133 are exposed. The height of the protrusion 71 from the surface of the ceiling in FIG. 3A is 5 mm, and the height of the protrusion 71 from the surface in FIG. 3B is 10 mm.

FIG. 3C is an example of the present embodiment, and an example of the recess 70. The recesses 70a and 70b having a depth of 5 mm is doubly formed into ring shapes.

FIG. 3D is an example of the present embodiment, and a protrusion is formed between the recesses 70a and 70b having a depth of 5 mm. The protrusion protrudes 10 mm from the bottom part of the recesses 70a and 70b, that is, 5 mm from the surface of the ceiling.

In such a configuration, the surface plasma of the microwave is generated in the following process conditions.

[Process Conditions]

| Gas Type | Ar gas | |
|---|---|---|
| Power of Microwave | 400 | W |
| Frequency of Microwave | 860 | MHz |
| Pressure | 10 | Pa |

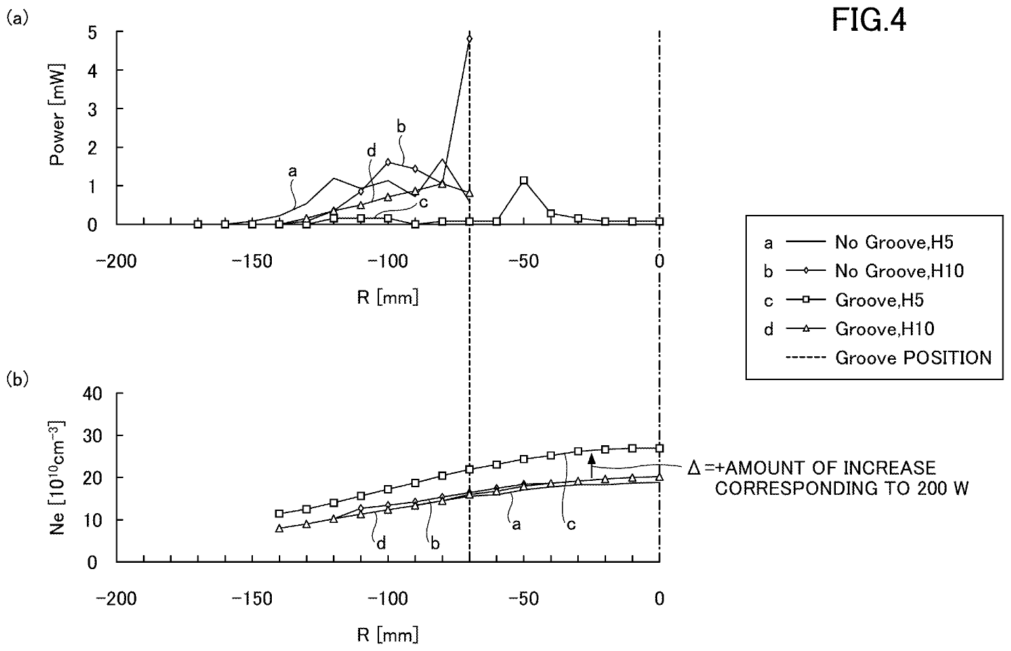

FIG. 4 shows the result. A Graph in FIG. 4(a) shows an example of a state of an electric field of surface wave plasma that propagates along a surface of the ceiling. The horizontal axis shows a distance R from the center (right end in the graph) of the ceiling, and the vertical axis shows electric field intensity power (mW). A line at −70 mm of the horizontal axis is a position where the protrusion 71 or the recess 70 is formed. According to the result, the electric field intensities of the surface plasma on the outer peripheral side of the position of the recesses 70 shown by the lines “c” and “d” in which the recesses 70 are formed as illustrated in FIGS. 3C and 3D are lower than the electric field intensities of the surface plasma on the outer peripheral side of the position of the protrusions 71 shown by the lines “a” and “b” in which the protrusions 71 are formed as illustrated in FIGS. 3A and 3B. In short, by providing the recess 70 rather than the protrusion 71 in the surface of the ceiling, interception efficiency of the electric field of the surface plasma can be enhanced. Moreover, the result in FIG. 4(a) indicates that providing the recess 70 having the depth of 5 mm illustrated in FIG. 3C can enhance the interception efficiency of the electric field of the surface plasma more highly than providing the recess 70 (the central portion has the height of 10 mm) illustrated in FIG. 3D.

The evaluation result indicates that it is preferable to form a recess having a depth of about 5 mm, that is, λₛₚ/4 so as to surround each of the openings 150 from which the micro transmission members 123 and 133 are exposed. Furthermore, the result indicates that the interception efficiency of the electric field of the surface plasma when providing the protrusion 71 is lower than the interception efficiency of the electric field of the surface plasma when providing the recess 70. Here, the wavelength λₛₚ of the surface wave of the microwave propagating along the surface of the ceiling from the opening 150 of the ceiling corresponds to a wavelength of the microwave flowing along the surface of plasma, and falls within a range from about 1/10 to about 1/20 of a free space wavelength of plasma in a vacuum.

The graph in FIG. 4(b) shows an example of electron density of plasma generated in the above process conditions. The electron density of plasma is synonymous with plasma density.

FIG. 4(b) indicates that a line “c” in the graph of FIG. 4(b), which shows the electron density of plasma when the recess 70 of FIG. 3C is formed, is much higher in the electron density inside the broken line of −70 mm in the horizontal axis than the electron density of plasma of lines “a” (that is, when the protrusion 71 of FIG. 3A is formed), “b” (that is, when the protrusion 71 of FIG. 3B is formed), and “d” (that is, when the recess 70 of FIG. 3D is formed). The result indicates that power adsorption efficiency on the inner side of the recess can be increased by about +200 W in an example of FIG. 4 by providing the recess having a depth of 5 mm so as to surround each of the openings 150 in the ceiling.

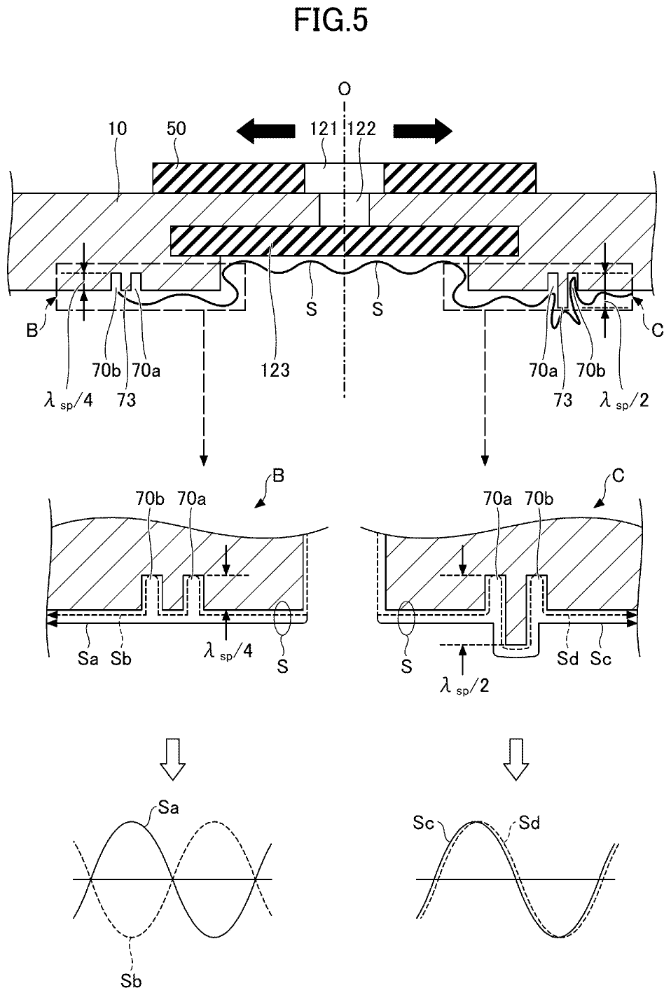

A reason why the interception efficiency of the electric field of the surface plasma is high when the depth of the recess is designed at 5 mm is described below with reference to FIG. 5. The left side of the central axis O illustrates a model of the recesses 70a and 70b of FIG. 3C. The right side of the central axis O illustrates a model of the recesses 70a and 70b of FIG. 3D.

A region B surrounded by a broken line is enlarged and illustrated in the second-row and left-side diagram, which schematically illustrates a state in which the surface wave S of the microwave propagates. A region C surrounded by a broken line is enlarged and illustrated in the second-row and right-side diagram, which schematically illustrates a state in which the surface wave S of the microwave propagates.

The surface wave of the microwave illustrated in the enlarged diagram of the region B includes a surface wave Sa that travels in a straight line without going into the recesses 70a and 70b along the surface of the ceiling and a surface wave Sb that travels along the surface of the ceiling while going into the recesses 70a and 70b.

The surface wave Sb that travels along the surface while going into the recesses 70a and 70b propagates along the inner surface of the recesses 70a and 70b, goes and back by reflecting from the bottom, and joins up with the surface wave Sa. At the junction, the phase of the surface wave Sb deviates from the phase of the surface wave Sa by a distance of λg/2 (=(λg/4)×2) that is a distance when the surface wave Sb goes back and forth in the recesses 70a and 70b. As a result, as illustrated by the surface waves Sa and Sb in the diagram at the bottom on the left side, the joined surface waves Sa and Sb cancel each other. Thus, when the depth of the recesses 70a and 70b are designed at 5 nm, the interception efficiency of the electric field of the surface plasma becomes high, and the power absorption efficiency in the recesses 70a and 70b becomes high, thereby increasing the plasma density.

In contrast, in the surface wave of the microwave illustrated in the enlarged diagram of the C region, the phase of the surface wave Sb that travels while going into the recesses 70a and 70b deviates from the phase of the surface wave Sa by the deviation of +λg/2 in the case of FIG. 3C. Because the deviation in FIG. 3C is λg/2, the phase of the surface wave Sd deviates from the surface wave Sc by λg. As a result, as illustrated by the surface waves Sc and Sd in the diagram at the bottom on the right side, the joined surface waves Sc and Sd heighten with each other.

Because of the reasons described above, the interception efficiency of the electric field caused by the surface plasma of the microwave by the recesses 70a and 70b in FIG. 3D becomes lower than the interception efficiency of the electric field caused by the surface plasma of the microwave by the recesses 70a and 70b in FIG. 3C. As a result, as shown in FIG. 4(a), the electric field intensity of the line “d” on the outer side of the line of −70 mm on the horizontal axis is higher than the electric field intensity of the line “c” on the outer side of the line of −70 mm on the horizontal axis. Thus, the power absorption efficiency shown by a line “c” is significantly greater than the power absorption efficiency shown by a line “d.” The result indicates that it is more difficult for the recesses 70a and 70b in FIG. 3D to increase the plasma density than the case of forming the recesses 70a and 70b in FIG. 3C in the ceiling.

As discussed above, the recess 70 having a depth of about 5 mm (i.e., λg/4) is formed into a ring shape in the surface of the ceiling of the microwave plasma processing apparatus according to the embodiment such that the ring has a diameter in a range from a diameter φ of the opening+10 mm to the diameter φ+100 mm when the opening in the ceiling has the diameter cp. The number of the recess 70 may be one or more. However, the number of the recess 70 is preferably multiple because the multiple recesses 70 can enhance the field interception efficiency more than the single recess 70.

In the meantime, the microwave plasma processing apparatus 100 according to the embodiment has the microwave transmittal parts 40, the microwave emission members 50, the slots 122 and 123, and the microwave transmission members 123 and 133 seven by seven, but may have the microwave transmittal parts 40, the microwave emission members 50, the slots 122 and 123, and the microwave transmission members 123 and 133 one by one. In this case, a single recess 70 is provided so as to surround a single microwave transmission member 122 or 133.

[Variation of Process Condition (Pressure, Gas Type) and Electric Field Interception Efficiency]

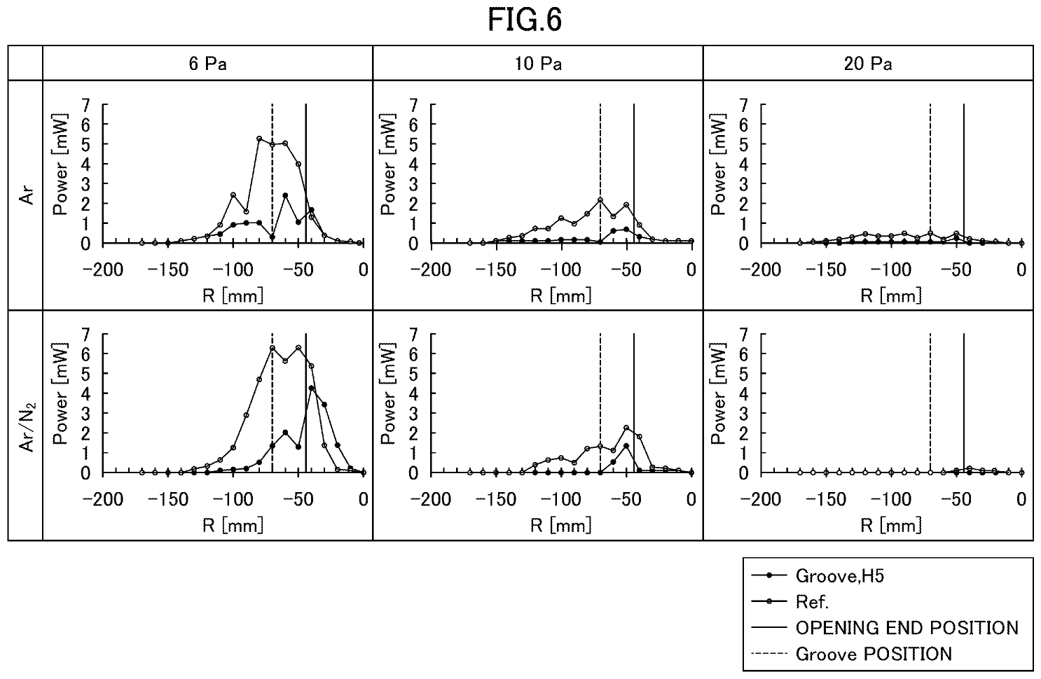

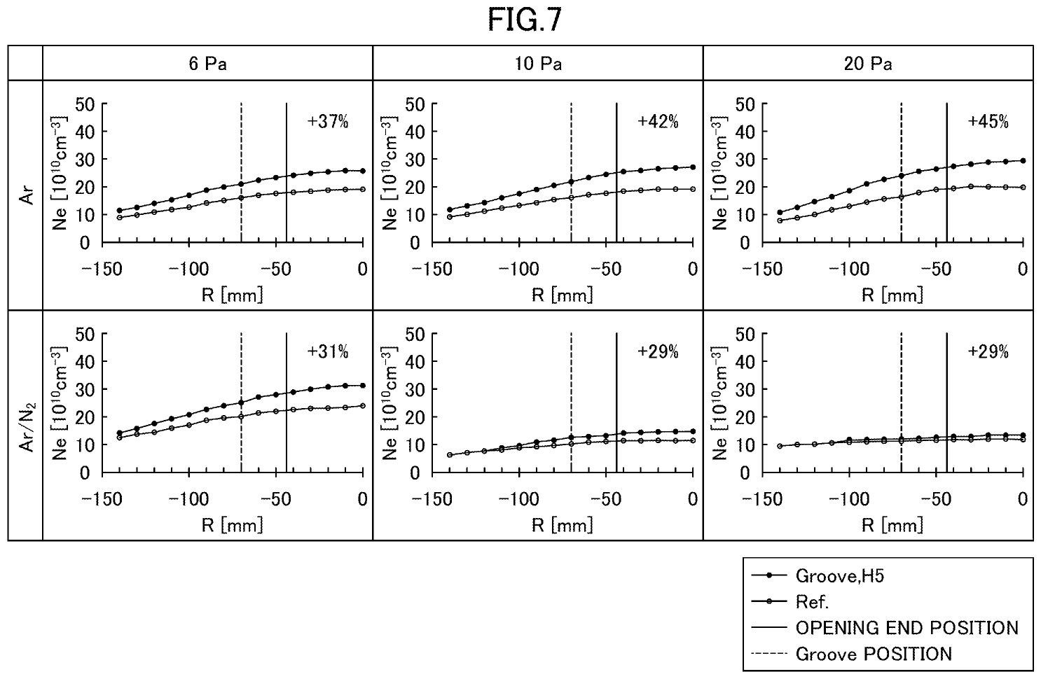

Next, an example of an evaluation result of electric field interception efficiency of a recess of the microwave plasma processing apparatus 100 according to the embodiment is described below while comparing a comparative example with reference to FIGS. 6 and 7. FIG. 6 shows an example of an electric field intensity of surface wave plasma of a microwave that propagates along the surface of the ceiling when process conditions of a pressure and a gas type are changed. FIG. 7 shows an example of an electron density of plasma when process conditions of a pressure and a gas type are changed.

FIG. 6 indicates that when a recess 70 having a depth of 5 mm is provided in a surface of a ceiling, the electric field intensity outside a broken line of −70 mm where the recess 70 is formed is lower than the case without providing any recess 70 shown by “Ref.” in any cases of 6 Pa, 10 Pa and 20 Pa, and that the recess 70 improves the electric field interception efficiency of the surface wave. Moreover, FIG. 7 indicates that when a recess 70 having a depth of 5 mm is provided in the surface of the ceiling, plasma density inside the broken line of −70 mm where the recess 70 is formed increased by about 1.3 times to about 1.5 times from the case without any recess shown by “Ref.” in any cases of 6 Pa, 10 Pa and 20 Pa. It is likely that the adsorption of input power of the microwave is improved, thereby increasing the plasma density up to the maximum 1.5 times relative to the input power. The result was similar in using Ar gas plasma, and Ar gas and N₂ gas plasma.

Here, when the pressure in the process chamber is in a range of 5 to 50 Pa, an appropriate value of the depth varies depending on the frequency of microwave, and an appropriate value of the position varies depending on the pressure and gas type. More specifically, when a mixed gas of Ar and N₂ is used, the appropriate value of the position of the recess 70 moves inward as the pressure is increased. Furthermore, when Ar gas is used, the appropriate value of the position of the recess 70 moves outward as the pressure is decreased.

[Variation]

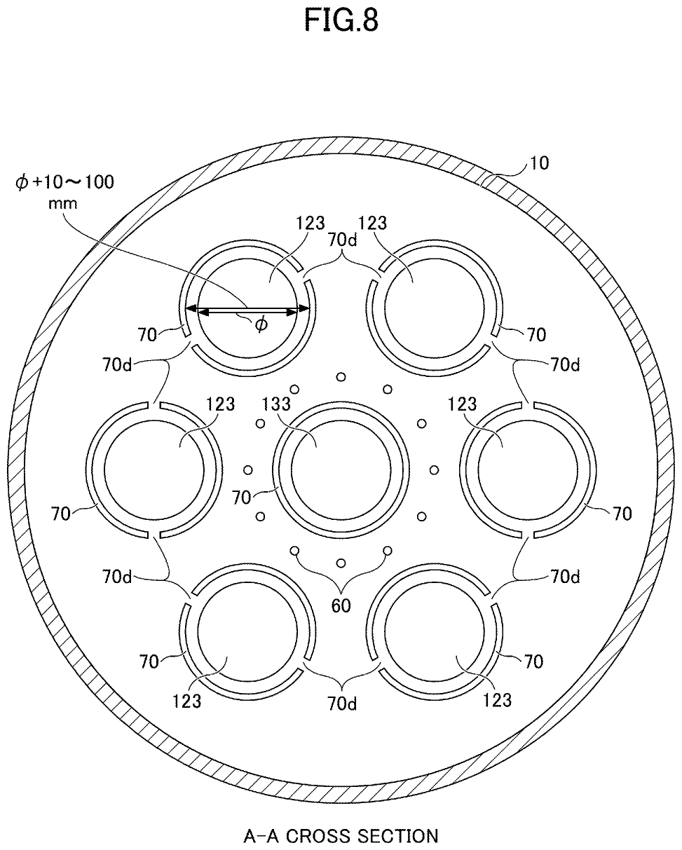

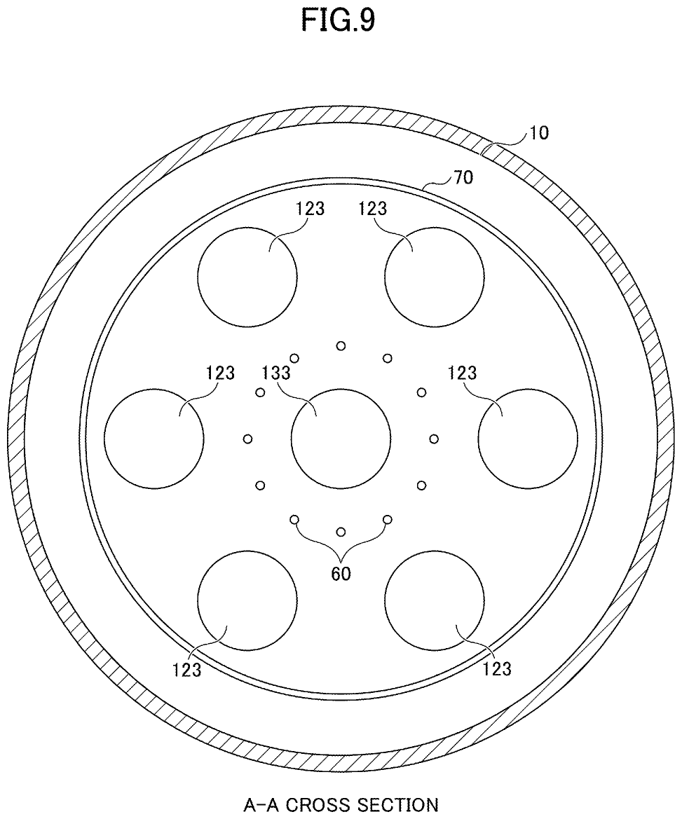

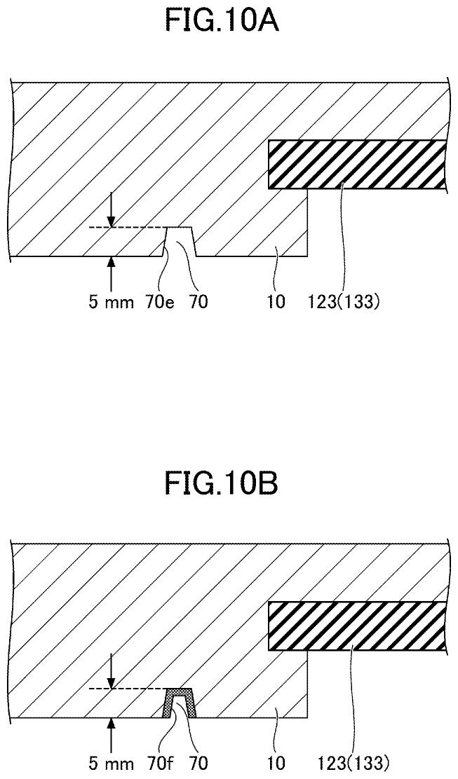

Finally, a recess 70 of the ceiling of the microwave plasma processing apparatus according to a variation is described below with reference to FIGS. 8 through 10. FIG. 8 is a diagram illustrating an example of a recess 70 in a ceiling of a microwave plasma processing apparatus of a first variation according to the present embodiment (an example of an A-A cross section in FIG. 1). FIG. 9 is a diagram illustrating an example of in a ceiling of a microwave plasma processing apparatus of a second variation according to the present embodiment (an example of an A-A cross section in FIG. 1). FIG. 10 is a cross-sectional view illustrating an example of a recess in a ceiling of a microwave plasma processing apparatus of a third variation according to the present embodiment.

(First Variation)

Recesses 70 in the first variation illustrated in FIG. 8 include two openings 70d formed at positions opposite to each other depending on positions of the microwave transmission members 123 adjacent to each other in a circumferential direction. The openings 70d have the same height as the height of the surface of the ceiling, and have no recess 70. The surface waves of the microwaves partially propagate toward the peripheral side of the recesses 70 from the openings 70d. Ends of the openings 70 are formed in parallel with each other, but are not limited to the example, and are preferably formed to open in a range of about 30° to about 60°.

Thus, by providing two openings 70d on the adjacent microwave transmission member 123 side in the circumferential direction in each recess 70, the surface wave plasma of the microwave propagating along the ceiling partially leaks outward from the openings 70d. Thus, the plasma density can be increased in a region on the inner side of each of the recesses 70 while preventing the plasma density between the adjacent microwave transmission surface wave plasma from decreasing. As a result, the process performance can be improved.

(Second Variation)

A single recess 70 of the microwave plasma processing apparatus according to a second variation is formed into a ring shape so as to surround the entire openings from which the plurality of microwave transmission members 123 and 133 are exposed. This can also enhance the power absorption efficiency on the inner side of the recess 70 and can increase the plasma density. As a result, the process performance can be improved.

(Third Variation)

As illustrated in FIG. 10A, a recess 70 of a microwave plasma processing apparatus according to a third variation is formed into a tapered shape such that side walls 70e incline inward to the bottom. Moreover, as illustrated in FIG. 10B, an inner wall surface of the recess 70 may be coated with a protective film 70f made of yttria (Y₂O₃) by thermal spray. The protective film 70f made of yttria may coat not only the recess 70 having the tapered side surfaces but also the side surfaces and the bottom surface of the recess 70 having the vertically shaped side surfaces. Thus, the plasma resistance of the recess 70 can be improved, thereby preventing generation of a particle. In any case of FIG. 10A and FIG. 10B, the depth of recess 70 may be preferably set at about 5 mm. Furthermore, the recess 70 formed in the present embodiment and the first through third variations may be an exact circle or an ellipse.

As described above, the microwave plasma processing apparatus 100 includes the recess 70 having the depth of λg/4 or λg/4±λg/8 formed in the ceiling at a predetermined distance on the outside from the openings (i.e., emission region of the microwave, the position of the microwave transmission members 123 and 133) in the ceiling. Thus, the recess 70 can improve the interception efficiency of the electric field of the surface plasma of the microwave and the power absorption efficiency on the inner side of the recess 70, and can increase the plasma density. As a result, the process performance can be improved.

(Fourth Variation)

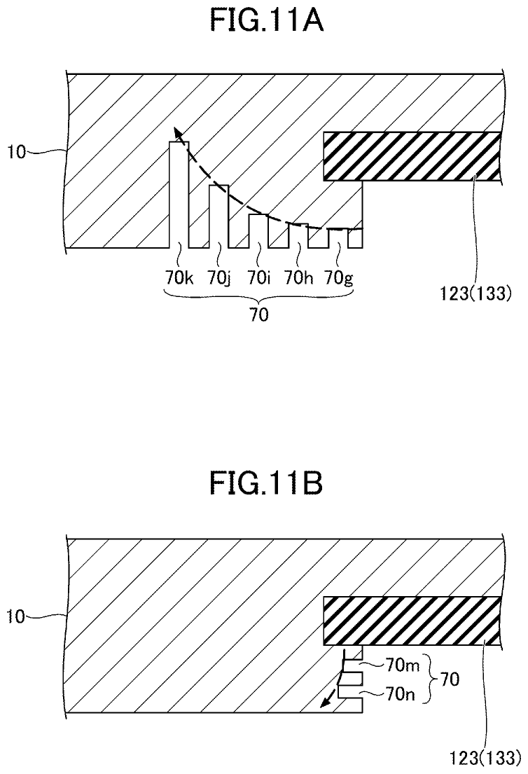

Next, a recess 70 in a ceiling of a microwave Plasma processing apparatus of a fourth variation according to the embodiment is described below with reference to FIGS. 11A and 11B. In the fourth variation, two or more recesses having different depths are formed on the outer side of the opening of the lid body 10 that is closed by the microwave transmission member 123 or 133 such that electron density of plasma increases in an exponential manner relative to the wavelength λₛₚ of the surface wave of the microwave.

In FIG. 11A, five recesses 70g, 70h, 70i, 70j and 70k having different depths are formed such that the electron density of plasma varies in an exponential manner relative to the wavelength λₛₚ. In FIG. 11B, two recesses 70m and 70n having different depths are formed such that the electron density of plasma varies in an exponential manner relative to the wavelength λₛₚ.

The recesses 70g, 70h, 70i, 70j and 70k are formed in a back surface of the ceiling on the outer side of the opening 123 or 133 of the lid body 10. The recesses 70m and 70n illustrated in FIG. 11B are formed in a side surface of the ceiling on the outer side of the opening 123 or 133. The structure in FIG. 11A and FIG. 11B may be combined with each other.

The depth of two or more of the recesses 70 preferably becomes shallower toward the opening 123 or 133 of the lid body 10 and becomes deeper with the increasing distance from the opening 123 or 133 of the lid body 10. Moreover, the number of the recesses 70 is not limited to this example, but may be three, four or more as long as the number is plural. Moreover, the distance between the recesses 70 is preferably set at about λₛₚ/4 and even, but is not limited to this example. In addition, two or more of the recesses 70 illustrated in the fourth variation can be applied to the microwave plasma processing apparatus by combining the position and/or the shape of the recess 70 illustrated in the first through third variations.

Thus, the recesses 70 can cut the surface wave (electromagnetic wave) of the microwave while keeping the electron density of plasma high. The reason thereof is described below.

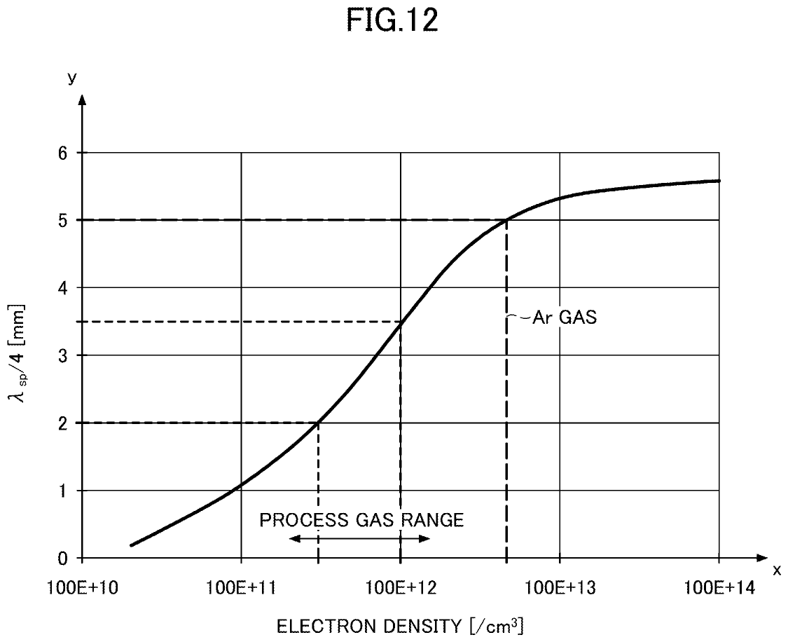

FIG. 12 is a graph showing a relationship between a wavelength λₛₚ of a surface wave of a microwave in a sheath of a microwave plasma processing apparatus of a fourth variation according to an embodiment. The horizontal axis x shows electron density, and the vertical axis y shows ¼ of the wavelength λₛₚ of the surface wave of the microwave. In a process gas region shown by broken lines, with respect to a process gas used for a plasma process, the wavelength λₛₚ/4 and the electron density of the plasma have approximately a liner relationship. Moreover, in a range from the process gas range to the argon gas range, the wavelength λₛₚ/4 and the electron density have a liner relationship.

Because the present graph shows the electron density of plasma relative to the wavelength λₛₚ/4 by a logarithm function, the electron density of plasma changes in an exponential manner relative to the wavelength λₛₚ/4 in the process gas range. That is, wavelength λₛₚ changes in an exponential manner depending on the electron density of plasma in the process gas range. In other words, the wavelength λₛₚ/4 of the surface wave of the microwave changes depending on the electron density of plasma, the recess 70 is preferably formed to have a depth of the wavelength λₛₚ/4 corresponding to the electron density of the targeted plasma.

A plurality of recesses 70 having different depths varied in an exponential manner in accordance with the electron density of plasma as illustrated in FIGS. 11A and 11B using the above plasma characteristics, is provided. Thus, the plurality of recesses 70 targeting the electron density region corresponding to the process conditions can be formed. As a result, the recesses 70 can cut the surface wave of the microwave while keeping the electron density of plasma high.

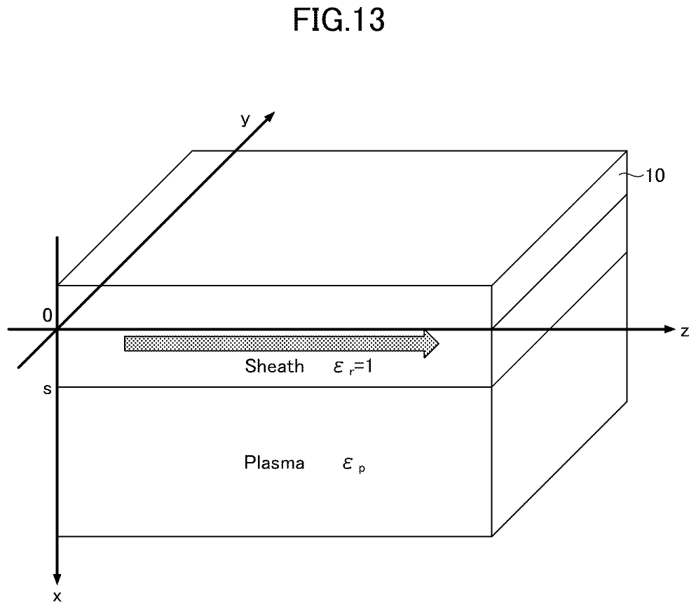

The relationship between the wavelength λ₃₀ of the surface wave of the microwave and the electron density of plasma shown in FIG. 12 can be derived as follows. FIG. 13 illustrates a state of forming a sheath and plasma under the lid body 10 provided in (y, z) directions as a system used for calculations for introducing the relationship between the wavelength λₛₚ of the surface wave of microwave and the electron density of plasma. When a relative permittivity of the sheath is made εᵣ (=1), and when a relative permittivity of the plasma is made εₚ, the following formula (1) is derived from Maxwell's equation and the equation of motion of an electron.

(εₚ/εᵣ)×(α/β)tanh(αs)+1=0 (1)

A letter α shows the number of waves of the microwave in the x direction of the sheath. A letter β shows the number of waves of the microwave in the x direction in the plasma. A letter s shows the thickness of the sheath.

The letter α is shown by a formula (2), and the letter β is shown by a formula (3).

α²=k²−(ω/c)² (2)

β²=k²−εₚ(ω/c)² (3)

The formula (3) can be converted to the following formula (4).

$${β}^{2} = {k}^{2} - {( \frac{ω}{c} )}^{2} + \frac{i - i γ}{1 + {γ}^{2}} {( \frac{ω}{{ω}_{p}} )}^{2} \qquad ( 4 )$$

The letter γ is a collision frequency between an electron and a neutral particle, and is determined by a pressure of system. The letter ω is an angle rate of the microwave having an input frequency, and the letter c is a speed of light. The letter ωₚ is an electron plasma frequency, and a function of the electron density of plasma.

The letter k in formula (2) shows the number of waves of the surface wave of the microwave in the sheath in the z direction. The letter k in formula (4) shows the number of waves of the surface wave of the micro wave in the plasma in the z direction. Because the numbers of waves of the sheath and the plasma are the same as each other in a contact surface in the z direction illustrated in FIG. 13, the numbers of k in formula (2) and in formula (4) are the same.

By assigning α and β defined by formula (2) and formula (4) to α and β in formula (1), the following formula (5) is derived.

λₛₚ=2Π/Re(k) (5)

Because the number of waves k of the surface wave of the microwave in the plasma is associated with the electron density ωₚ from formula (4), a relational expression between the wavelength λₛₚ of the surface wave of the microwave and the number of waves k of the surface wave of the microwave indicates the relationship between the wavelength λₛₚ of the surface wave and the electron density ωₚ.

As discussed above, the graph in FIG. 12 is derived from formula (4) and formula (5), and the wavelength λₛₚ of the surface wave of plasma depends on the electron density of plasma and varies in accordance with the electron density of plasma.

Hence, multiple recesses 70 that vary in depth in an exponential manner corresponding to the electron density range in accordance with process conditions are formed so as to have an effect of intercepting the surface wave that varies its wavelength λₛₚ depending on the electron density of plasma in a variety of process condition ranges. Thus, a probability that at least any of the plurality of recesses 70 becomes a groove having a depth of about λₛₚ/4 corresponding to the electron density range in accordance with the process conditions can be increased. In other words, forming the multiple recesses 70 that vary in depth in an exponential manner, the recesses 70 can exert an effect of increasing the interception efficiency of the electric field of the surface wave plasma of the microwave to the maximum. Thus, the power absorption efficiency on the inner side of the recesses 70 can be improved, and the plasma density can be increased. As a result, the process performance can be enhanced.

As discussed above, according to the embodiments, a plasma processing apparatus having a structure that can increase plasma density can be provided.

Although a microwave plasma processing apparatus has heretofore been described with reference to the embodiments and the variations thereof, the microwave plasma processing apparatus according to the present disclosure is not limited to such embodiments, and various modifications and improvements may be made without departing from the scope of the invention. Elements described in connection with these embodiments may be combined with each other as long as consistency is maintained.

A semiconductor wafer W has been used as an example of an object to be processed. The object to be processed is not limited to the embodiments, and may alternatively be various types of substrates for use in an LCD (liquid crystal display) or an FPD (flat panel display), etc.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention. Although the embodiments of the present disclosure have been described in detail, it should be understood that the various changes, substitutions, and alterations could be made hereto without departing from the spirit and scope of the invention.

What is claimed is:

1. A microwave plasma processing apparatus, comprising:
a microwave supply part configured to supply a microwave;
a microwave emission member provided on a ceiling of a process chamber and configured to emit the microwave supplied from the microwave supply part; and
a microwave transmission member configured to close an opening provided in the ceiling and made of a dielectric substance that transmits the microwave via the microwave emission member,
wherein the ceiling has at least two recesses provided on an outer side of the opening, each of the at least two recesses having a depth different from each other.

2. The microwave plasma processing apparatus as claimed in claim 1, wherein at least one of the at least two recesses has a depth in a range of λₛₚ/4±λ₅₀/8 when a wavelength of a surface wave of the microwave traveling through the microwave transmission member and propagating along a surface of the ceiling from the opening is taken as λₛₚ.

3. The microwave plasma processing apparatus as claimed in claim 1, wherein the one of the at least two recesses has a depth that varies in an exponential manner as compared to a depth of the other of the at least two recesses.

4. The microwave plasma processing apparatus as claimed in claim 1, wherein the at least two recesses include one or more recesses distant outward in a range of 10 to 100 mm from an end of the opening.

5. The microwave plasma processing apparatus as claimed in claim 1, further comprising:
a plurality of openings arranged in a circumferential direction; and
a plurality of microwave transmission members, each of the plurality of microwave transmission members being configured to close a corresponding opening of the plurality of openings,
wherein each of the at least two recesses is formed into a ring shape to surround a corresponding opening of the plurality of openings from which each of the plurality of microwave transmission members is exposed.

6. The microwave plasma processing apparatus as claimed in claim 1, further comprising:
a plurality of openings arranged in a circumferential direction; and
a plurality of microwave transmission members, each of the plurality of microwave transmission members being configured to close a corresponding opening of the plurality of openings,
wherein each of the at least two recesses is formed into a ring shape to surround a corresponding opening of the plurality of openings from which the plurality of microwave transmission members is exposed.

7. The microwave plasma processing apparatus as claimed in claim 6, wherein each of the at least two recesses corresponding to each of the plurality of openings has a flat portion at a position opposite to an adjacent microwave transmission member or in the vicinity of the position opposite to the adjacent microwave transmission member.

8. The microwave plasma processing apparatus as claimed in claim 1, wherein each of the at least two recesses is formed into a tapered shape.

9. The microwave plasma processing apparatus as claimed in claim 1, wherein an inner wall of each of the at least two recesses is coated with yttria.

10. The microwave plasma processing apparatus as claimed in claim 1, wherein the at least two recesses are provided in a side surface or a back surface of the ceiling and on an outer side of the opening.

11. The microwave plasma processing apparatus as claimed in claim 1, wherein the at least two recesses become shallower toward the opening.

12. The microwave plasma processing apparatus as claimed in claim 1, wherein the at least two recesses become deeper toward the opening.

13. The microwave plasma processing apparatus as claimed in claim 1, wherein a distance between the at least two recesses is about λₐₚ/4 and even when a wavelength of a surface wave of the microwave traveling through the microwave transmission member and propagating along a surface of the ceiling from the opening is taken as λₛₚ.
